(19) United States
(12) Patent Application Publication
(10) Pub. No.: US 2012/0211724 A1
(43) Pub. Date: Aug. 23, 2012

(54) SEMICONDUCTOR LIGHT EMITTING DEVICE AND METHOD FOR MANUFACTURING SAME

(75) Inventors: Takuo KIKUCHI, Kanagawa-ken (JP); Hidehiko Yabuhara, Kanagawa-ken (JP)

(73) Assignee: Kabushiki Kaisha Toshiba, Tokyo (JP)

(21) Appl. No.: 13/353,762

(22) Filed: Jan. 19, 2012

(30) Foreign Application Priority Data
Feb. 21, 2011 (JP) 2011-034586

(51) Int. Cl. H01L 33/06

(52) U.S. Cl. 257/13; 438/45; 257/E33.008

(57) ABSTRACT

According to an embodiment, a semiconductor light emitting device includes an n-type semiconductor layer, a p-type semiconductor layer and a light emitting layer provided between the n-type semiconductor layer and the p-type semiconductor layer. The light emitting layer includes at least one quantum well, and the quantum well adjacent to the p-type semiconductor layer includes a first barrier layer and a second barrier layer, the first barrier layer nearer to the p-type semiconductor layer being doped with p-type impurity.

### CROSS-REFERENCE TO RELATED APPLICATIONS

This application is based upon and claims the benefit of priority from Japanese Patent Application No. 2011-034586, filed on Feb. 21, 2011; the entire contents of which are incorporated herein by reference.

### FIELD

Embodiments are related generally to a semiconductor light emitting device and a method for manufacturing the same.

### BACKGROUND

In the recent efforts toward low carbon society, it is important to increase the light emission efficiency of semiconductor light emitting devices to reduce power consumption. For instance, light emitting diodes (LED) are more resistant to vibration and power on/off, and have longer lifetime, than filament-based light sources such as electric bulbs and fluorescent lamps. Furthermore, LED allows low voltage operation and easy lighting control. Thus, application of LED to the field of illumination is rapidly expanding. In particular, attention is focused on blue LED, which can emit light of various colors by combination with phosphors.

A blue LED includes a light emitting layer provided between an n-type nitride semiconductor layer and a p-type nitride semiconductor layer. The light emitting layer includes a quantum well layer, where electrons and holes are recombined to emit light with a wavelength corresponding to the energy gap of the quantum well layer. Hence, to increase the light emission efficiency of the blue LED, it is effective to increase the recombination efficiency of electrons and holes.

However, in a semiconductor light emitting device made of e.g. nitride semiconductor, lattice strain occurs between the quantum well and the quantum barrier therearound. The lattice strain generates a polarization electric field, or a so-called piezoelectric field. The piezoelectric field induced in the quantum well inhibits recombination of electrons and holes. Thus, there is demand for a semiconductor light emitting device capable of reducing the piezoelectric field induced in the quantum well to increase the light emission efficiency.

### BRIEF DESCRIPTION OF THE DRAWINGS

FIGS. 1A and 1B are schematic cross-sectional views illustrating a semiconductor light emitting device according to a first embodiment;

FIGS. 2A and 2B are schematic band diagrams illustrating a quantum well of semiconductor light emitting device according to the first embodiment;

FIG. 3 is a graph illustrating a characteristic of the semiconductor light emitting device according to the first embodiment;

FIGS. 4A and 4B are schematic band diagrams illustrating the quantum well of the semiconductor light emitting device according to the first embodiment;

FIGS. 5A and 5B are schematic cross-sectional views illustrating a semiconductor light emitting device according to a variation of the first embodiment;

FIGS. 6A and 6B are schematic band diagrams illustrating a quantum well of the semiconductor light emitting device according to the variation of the first embodiment;

FIGS. 7A and 7B are schematic cross-sectional views illustrating a semiconductor light emitting device according to a second embodiment;

FIGS. 8A and 8B are schematic cross-sectional views illustrating a light emitting layer of a semiconductor light emitting devices according to a third embodiment;

FIG. 9 is a schematic band diagram illustrating a quantum well of a semiconductor light emitting device according to a comparative example.

### DETAILED DESCRIPTION

According to an embodiment, a semiconductor light emitting device includes an n-type semiconductor layer, a p-type semiconductor layer and a light emitting layer provided between the n-type semiconductor layer and the p-type semiconductor layer. The light emitting layer includes at least one quantum well, and the quantum well adjacent to the p-type semiconductor layer includes a first barrier layer and a second barrier layer, the first barrier layer nearer to the p-type semiconductor layer being doped with p-type impurity.

Embodiments of the invention will now be described with reference to the drawings. In the following embodiments, like portions in the drawings are labeled with like reference numerals. The detailed descriptions of the like portions are omitted as appropriate, and the different portions are described.

### First Embodiment

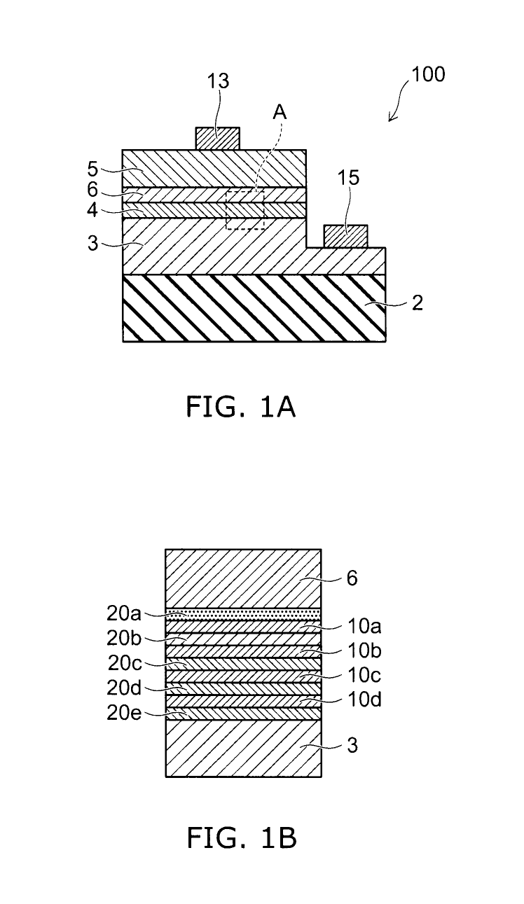

FIG. 1A is a schematic view showing a cross section of a semiconductor light emitting device 100 according to a first embodiment. FIG. 1B shows the structure of the region A enclosed with the dashed line in FIG. 1A. The semiconductor light emitting device 100 illustrated in the embodiment is a so-called blue LED made of nitride semiconductor.

The semiconductor light emitting device 100 includes an n-type GaN layer 3 as an n-type semiconductor layer provided on a substrate 2, a p-type GaN layer 5 as a p-type semiconductor layer, and a light emitting layer 4 provided between the n-type GaN layer 3 and the p-type GaN layer 5. Furthermore, a p-type AlGaN layer 6 is provided between the light emitting layer 4 and the p-type GaN layer 5. The p-type AlGaN layer 6 is a so-called block layer for blocking the flow of electrons from the light emitting layer 4 to the p-type GaN layer 5. This can increase the electron density in the light emitting layer 4 to facilitate recombination of electrons and holes.

On the surface of the p-type GaN layer 5 is provided a p-electrode 13. The p-type GaN layer 5, the p-type AlGaN layer 6, and the light emitting layer 4 are selectively mesa-etched. On the exposed surface of the n-type GaN layer 3 is provided an n-electrode 15. Furthermore, a transparent electrode may be formed on the surface of the p-type GaN layer 5.

On the other hand, as shown in FIG. 1B, the light emitting layer 4 is provided between the n-type GaN layer 3 and the p-type AlGaN layer 6, and includes a plurality of quantum wells. The quantum well is composed of two barrier layers and a well layer provided therebetween. The light emitting layer 4 includes well layers 10a-10d, respectively provided between barrier layers 20a-20e. For instance, the barrier layers 20a-20e are GaN layers, and the well layers 10a-10d are InₓGa₁₋ₓN layers (x=0.1-0.15). Each of the barrier layers 20a-20e can be provided with a thickness of 4-10 nm, and each of the well layers 10a-10d can be provided with a thickness of 2-5 nm. Thus, energy levels of the well layers 10a-10d provided between the barrier layers 20a-20e are quantized, so as to form a plurality of quantum wells.

InₓGa₁₋ₓN has a narrower bandgap than GaN and AlGaN. Thus, emission light emitted from the well layers 10a-10d has a longer wavelength than the band edge light emission of GaN and AlGaN. Hence, the emission light is transmitted through the p-type AlGaN layer 6 and the p-type GaN layer 5, and emitted outside.

For instance, a sapphire substrate is used for the substrate 2. The n-type GaN layer 3, the light emitting layer 4, the p-type AlGaN layer 6, and the p-type GaN layer 5 are sequentially formed on the substrate 2 by using e.g. the MOCVD (metal organic chemical vapor deposition) method. A GaN buffer layer without impurity doping may be provided between the substrate 2 and the n-type GaN layer 3, for instance.

The semiconductor light emitting device 100 emits light due to recombination of electrons and holes inside the quantum well of the light emitting layer 4. Electrons and holes are injected by a driving current supplied between the p-electrode 13 and the n-electrode 15. The proportion of light emission in the quantum well adjacent to the p-type GaN layer 5 is higher than that of light emission in the other quantum wells. That is, the light emission in the quantum well including the well layer 10a is accounted for a large fraction of the emission light emitted from the light emitting layer 4. Thus, the light emission efficiency can be effectively increased by facilitating recombination of electrons and holes in the well layer 10a.

In the embodiment, the first barrier layer 20a and the second barrier layer 20b are provided on both sides of the well layer 10a, wherein the barrier layer 20a nearer to the p-type GaN layer 5 is doped with p-type impurity. That is, the barrier layer 20a contains p-type impurity at a higher concentration than the background level without impurity doping. This reduces the polarization electric field induced inside the well layer 10a, and can increase the recombination probability of electrons and holes.

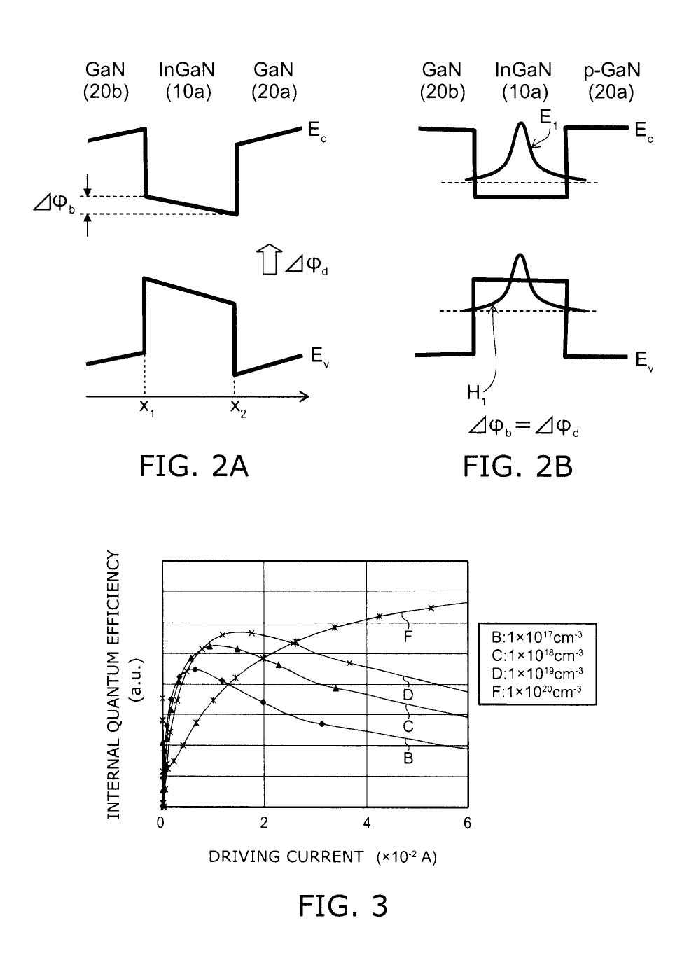

FIGS. 2A and 2B show band diagrams of a quantum well including the well layer 10a. More specifically, FIG. 2A is a band diagram in the case where the barrier layer 20a is not doped with p-type impurity. On the other hand, FIG. 2B is a band diagram in the case where the barrier layer 20a is doped with p-type impurity.

In the case where the InGaN layer as the well layer 10a and the GaN layers as the barrier layers 20a and 20b are provided without impurity doping, the energy level in the well layer 10a decreases in the direction from the barrier layer 20b to the barrier layer 20a as shown in FIG. 2A.

For instance, the electron potential φ(x) at an arbitrary position x in the well layer 10a is given by Equation (1). Here, the electron potential refers to the energy level of the conduction band E_{C}.

$$ϕ ( x ) = \frac{1}{{ɛ}_{0} {ɛ}_{r}} \text{?} ( {P}_{total} + E ) d x + ϕ ( {x}_{l} ) \\ \text{?} \text{indicates text missing or illegible when filed} \qquad ( 1 )$$

∈ᵣ and ∈₀ are the dielectric constant of InGaN and the vacuum permittivity, respectively. Pₜₒₜₐₗ is the polarization electric field in the quantum well, including both spontaneous polarization and piezoelectric polarization. E is the external electric field. φ(x₁) is the electron potential at the edge x₁ of the well layer 10a on the barrier layer 20b side.

If the width of the well layer 10a is narrow and the external electric field E is uniform, then the electron potential variation Δφ_{b} between x₁ and the edge x₂ of the well layer 10a on the barrier layer 20a side is given by Equation (2).

$${Δϕ}_{b} = \frac{1}{{ɛ}_{0} {ɛ}_{r}} \text{?} ( {P}_{total} + E ) d x = \frac{( {P}_{total} + E ) }{{ɛ}_{0} {ɛ}_{r}} Δ x \\ \text{?} \text{indicates text missing or illegible when filed} \qquad ( 2 )$$

Here, Δx is the width of the well layer 10a.

On the other hand, in the case where the barrier layer 20a is doped with p-type impurity, the potential shift Δφ_{d} of the conduction band E_{C} and the valence band E_{V} is given by Equation (3).

$${Δϕ}_{d} = kT ln ( \frac{{N}_{a 2}}{{N}_{a 1}} ) \qquad ( 3 )$$

Here, k is the Boltzmann constant, and T is the absolute temperature. Nₐ₁ is the background ionized acceptor concentration with no impurity doping. Nₐ₂ is the ionized acceptor concentration with p-type impurity doping.

Equations (4a) and (4b) represent the relationship between the concentration N_{A1} of p-type impurity contained (doped) in the barrier layer and the ionized acceptor concentration Nₐ₁, and the relationship between N_{A2} and the ionized acceptor concentration Nₐ₂, respectively.

$$\begin{matrix}{N}_{a 1} = \frac{{N}_{A 1}}{1 + {g}_{A} exp \{ \frac{{E}_{V} + {E}_{A} - {E}_{F 1} - q ( {P}_{total} + E )}{KT} \}} & ( 4 a ) \\ {N}_{a 2} = \frac{{N}_{A 2}}{1 + {g}_{A} exp \{ \frac{{E}_{V} + {E}_{A} - {E}_{F 2} - q ( {P}_{total} + E )}{KT} \}} & ( 4 b )\end{matrix}$$

Here, E_{A} is the excitation energy of a hole from the acceptor level to the valence band E_{V}. E_{F1} and E_{F2} are Fermi levels, q is the unit charge, and g_{A} is the degeneracy of the valence band.

N_{A1} is the background concentration of p-type impurity, and N_{A2} is the concentration of p-type impurity doped in the barrier layer. When assuming N_{A2}>>N_{A1}, Equation (3) can be calculated as Δφ_{d}=E_{F1}−E_{F2} from Equations (4a) and (4b).

For instance, as shown in FIG. 2A, the electron potential variation Δφ_{b} in the well layer 10a can be compensated by shifting E_{C} and E_{V} of the barrier layer 20a upward. That is, doping the barrier layer 20a with p-type impurity may shift E_{c} and E_{V} of the barrier layer 20a upward by Δφ_{d} and reduce Δφ_{b}. Thus, the influence of the polarization electric field can be relaxed in the well layer 10a.

For instance, the width of the well layer 10a is set to 2 nm. If the polarization electric field Pₜₒₜₐₗ is 8×10⁻³ Cm⁻², and the external electric field E is 1×10⁻³ Cm⁻², then from Equation (2), Δφ_{b} is equal to 0.229 eV.

Here, the following values are used for the constants.

∈₀=8.85×10⁻¹² Fm⁻¹

∈ᵣ=8.9

k=1.38×10⁻²³ J/K

T=300 K

On the other hand, by using Equation (3), Δφ_{d} is determined as shown in TABLE 1. Here, the background p-type impurity concentration N_{A1} is set to 1×10¹⁵ cm⁻³.

TABLE 1

| | p-type impurity conc. (cm⁻³) | | | | |
|---|---|---|---|---|---|
| | 1 × 10¹⁶ | 1 × 10¹⁷ | 1 × 10¹⁸ | 1 × 10¹⁹ | 1 × 10²⁰ |
| Δφ_{d} (eV) | 0.059 | 0.119 | 0.178 | 0.238 | 0.297 |

As the doping amount of p-type impurity is increased, the conduction band E_{C} and the valence band E_{V} are shifted to the direction of increasing the potential. Thus, the electron potential variation Δφ_{b} due to the polarization electric field can be compensated by the amount of Δφ_{d} shown in TABLE 1. For instance, when the p-type impurity doping concentration N_{A2} is 1×10¹⁹ cm⁻³, Δφ_{d} is equal to 0.238 eV, which nearly coincides with Δφ_{b}, 0.229 eV.

FIG. 2B is an energy band diagram in the case where Δφ_{b} and Δφ_{d} are equal. In this case, the polarization electric field Pₜₒₜₐₗ is canceled by the electric field generated by the shift of E_{C} and E_{V}. Then, the electron potential inside the well layer 10a is made uniform as shown in this figure. As a result, in the well layer 10a, the peak position of the electron wavefunction E₁ and the peak position of the hole wavefunction H₁ can be coincided with each other.

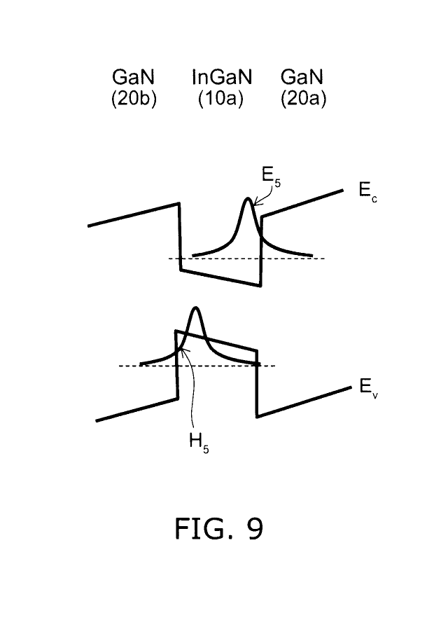

In contrast, as shown in FIG. 9, when an electron potential variation exists in the well layer 10a, there is a displacement between the peak position of the electron wavefunction E₅ and the peak position of the hole wavefunction H₅. Thus, the recombination probability of electrons and holes in the well layer 10a is decreased, and the light emission efficiency is reduced.

That is, in the semiconductor light emitting device 100 according to the embodiment, the barrier layer 20a is doped with p-type impurity at a concentration higher than the background level to reduce the polarization electric field inside the well layer 10a. Thus, the peak position of the electron wavefunction E₁ and the peak position of the hole wavefunction H₁ can be made close to each other. Thus, the recombination probability of electrons and holes in the well layer 10a can be increased, and the light emission efficiency can be improved.

FIG. 3 is a graph showing a simulation result for the internal quantum efficiency of the semiconductor light emitting device 100. The horizontal axis represents driving current, and the vertical axis represents internal quantum efficiency. The graphs B-F shown in this figure represent the variation of internal quantum efficiency for various concentrations of p-type impurity contained in the barrier layer 20a.

The simulation was carried out for the well layer 10a having higher contribution to light emission. As the p-type impurity for doping the barrier layer 20a, magnesium (Mg) was selected. The doping concentration was varied from 1×10¹⁷ to 1×10²⁰ cm⁻³.

As seen in graphs B-D shown in FIG. 3, when the p-type impurity for doping the barrier layer 20a is increased from 1×10¹⁷ cm⁻³ to 1×10¹⁹ cm⁻³, the internal quantum efficiency is gradually increased, and the peak value is increased by approximately 10%. Furthermore, as shown in graph F, when the p-type impurity is further increased to 1×10²⁹ cm⁻³, the peak of the internal quantum efficiency is significantly shifted to the high current side, and the value of internal quantum efficiency is increased. This indicates that the brightness of the semiconductor light emitting device is significantly increased.

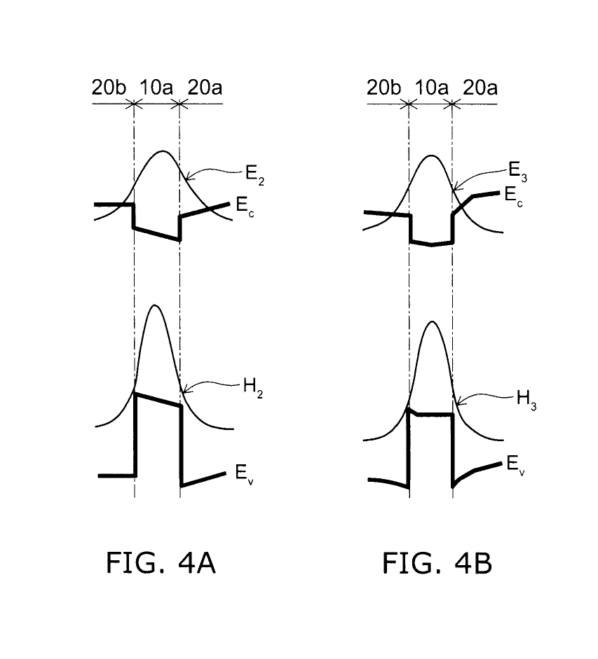

FIGS. 4A and 4B are band diagrams of a quantum well including the well layer 10a, and schematic diagrams showing simulation results for electron and hole wavefunctions. More specifically, FIG. 4A shows the case where the concentration of p-type impurity doped in the barrier layer 20a is 1×10¹⁷ cm⁻³, and corresponds to graph B in FIG. 3. On the other hand, FIG. 4B shows the case where the p-type impurity concentration is 1×10²⁰ cm⁻³, and corresponds to graph F in FIG. 3.

As shown in FIG. 4A, in the case where the p-type impurity concentration is 1×10¹⁷ cm⁻³, the electron potential inside the well layer 10a decreases in the direction from the barrier layer 20b to 20a. There remains a displacement between the peak position of the electron wavefunction E₂ and the peak position of the hole wavefunction H₂.

On the other hand, in the case where the p-type impurity concentration is 1×10²⁰ cm⁻³ shown in FIG. 4B, the electron potential is located at a nearly equal level on both ends of the well layer 10a. Thus, it is found that the polarization electric field is canceled. The peak position of the electron wavefunction E₃ and the peak position of the hole wavefunction H₃ are nearly coincided with each other.

Considering the aforementioned result calculated using Equations (2) and (3) and the above simulation result, the barrier layer 20a is preferably doped with p-type impurity in the concentration range of 1×10¹⁹-1×10²⁰ cm⁻³. Thereby, the electron potential is flattened inside the well layer 10a, and the light emission efficiency is significantly increased.

Specifically, the step of forming a light emitting layer 4 on the n-type GaN layer 3 is carried out as follows. An InGaN layer constituting the well layer 10a is grown on the barrier layer 20b. Then, for instance, the raw materials of TMG (trimethylgallium) and ammonia (NH₃) gas are supplied to a surface of the InGaN layer, and cyclopentadienylmagnesium (Cp₂Mg) is added to the raw materials. Thus, the GaN layer doped with Mg is grown on the InGaN layer, constituting the barrier layer 20a.

Here, to suppress diffusion of Mg from the GaN layer side into the InGaN layer, the growth can be performed with delayed timing of adding the doping gas that contains Cp₂Mg. For instance, considering the diffusion amount of Mg, the doping gas is added after the lapse of a prescribed time from starting the growth of the GaN layer. Alternatively, the doping gas may be controlled so that the added amount thereof is gradually increased.

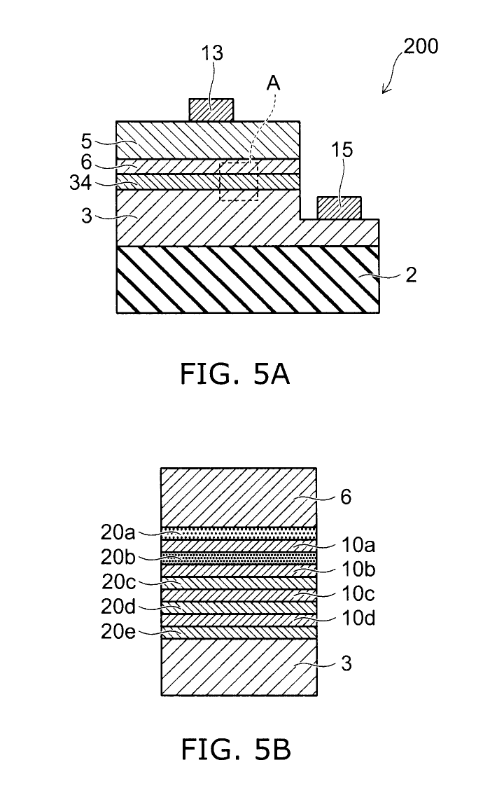

FIGS. 5A and 5B are schematic views showing a cross section of a semiconductor light emitting device 200 according to a variation of the embodiment. Here, FIG. 5B is a schematic view enlarging the region A enclosed with the dashed line in the light emitting layer 34 shown in FIG. 5A.

The semiconductor light emitting device 200 is different from the semiconductor light emitting device 100 in the configuration of the light emitting layer 34. More specifically, in the light emitting layer 34, the barrier layer 20a adjacent to the p-type AlGaN layer 6 is doped with p-type impurity, and furthermore, the barrier layer 20b is doped with n-type impurity. As the n-type impurity, for instance, silicon (Si) can be used for doping.

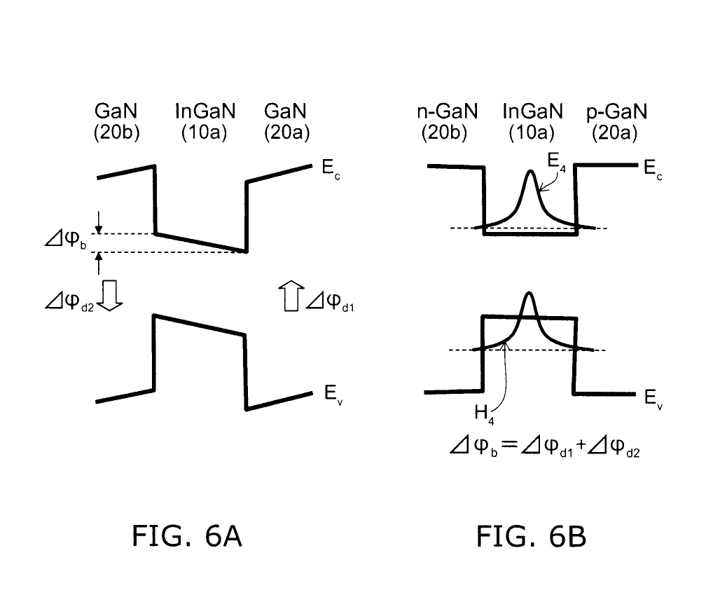

FIGS. 6A and 6B are band diagrams of a quantum well including the well layer 10a in the semiconductor light emitting device 200.

FIG. 6A shows the shift direction of the conduction band E_{C} and the valence band E_{V} in the case where the barrier layers 20a and 20b are doped with p-type impurity and n-type impurity, respectively. As described above, in the case where the barrier layer 20a is doped with p-type impurity, E_{C} and E_{V} are shifted to the direction of increasing the potential energy, i.e., upward in this figure. In contrast, in the barrier layer 20b doped with n-type impurity, E_{C} and E_{V} are shifted to the direction of decreasing the potential energy, i.e., downward in this figure.

The shift amount of E_{C} and E_{V} in the barrier layer 20a is denoted by Δφ_{d1}, and the shift amount of E_{C} and E_{V} in the barrier layer 20b is denoted by Δφ_{d2}. Then, as shown in FIG. 6B, the electron potential of the well layer 10a can be flattened by making the electron potential variation Δφ_{b} equal to the sum of Δφ_{d1} and Δφ_{d2}. Thus, the peak of the electron wavefunction E₄ and the peak of the hole wavefunction H₄ can be coincided with each other. This can increase the recombination probability of electrons and holes.

Thus, there is a contribution of the shift amount Δφ_{d2} of E_{C} and E_{V} in the barrier layer 20b. Hence, the shift amount Δφ_{d1} of E_{C} and E_{V} in the barrier layer 20a can be allowed to be smaller than the shift amount Δφ_{d} in the semiconductor light emitting device 100. That is, the concentration of p-type impurity doped in the barrier layer 20a can be decreased in the semiconductor light emitting device 200. Thus, for instance, the p-type impurity diffused from the barrier layer 20a into the well layer 10a may be decreased. Thereby, it is possible to suppress the decrease of light emission efficiency due to the p-type impurity diffused into the well layer 10a.

### Second Embodiment

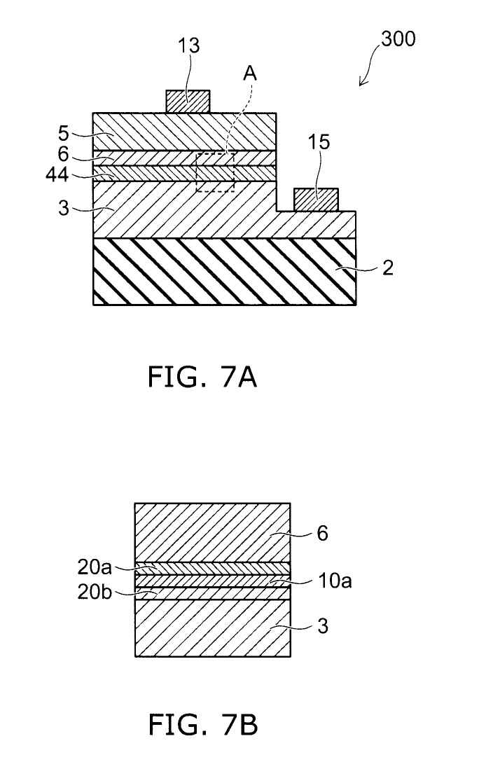

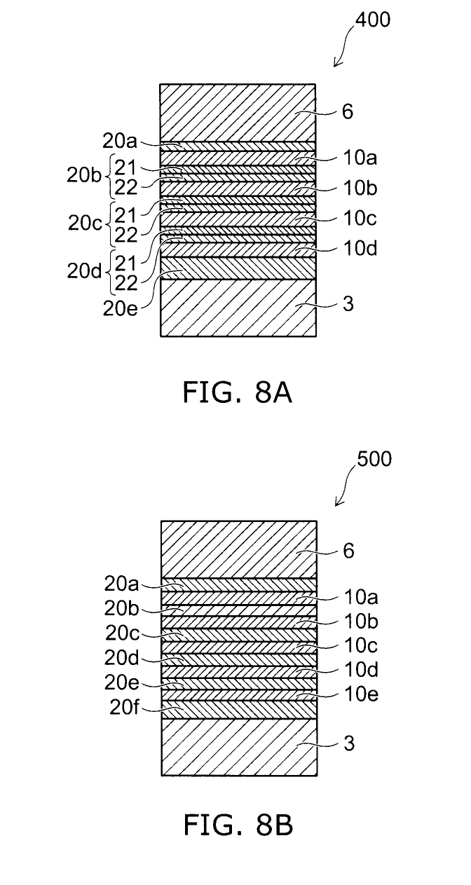

FIGS. 7A and 7B are schematic views showing a cross section of a semiconductor light emitting device 300 according to this embodiment. Here, FIG. 7B is a sectional view enlarging the region A enclosed with the dashed line in the light emitting layer 44 shown in FIG. 7A.

As shown in FIG. 7B, in the semiconductor light emitting device 300, the light emitting layer 44 includes one quantum well. Also in this case, the barrier layer 20a adjacent to the p-type AlGaN layer 6 is doped with p-type impurity. This can increase the recombination probability of electrons and holes in the well layer 10a to increase the light emission efficiency. Furthermore, the barrier layer 20b adjacent to the n-type GaN layer 3 may be doped with n-type impurity.

### Third Embodiment

FIGS. 8A and 8B are schematic views showing a cross section of the light emitting layer of semiconductor light emitting devices 400 and 500 according to this embodiment. Except the light emitting layer, the overall cross section of the semiconductor light emitting devices 400 and 500 has the same structure as that of the semiconductor light emitting device 100 shown in FIG. 1A.

In the semiconductor light emitting device 400 shown in FIG. 8A, in the barrier layers 20a-20d, the portion in contact with the edge on the p-type AlGaN layer 6 side of each well layer 10a-10d is doped with p-type impurity. That is, the barrier layer 20a adjacent to the AlGaN layer 6 is entirely doped with p-type impurity. On the other hand, the barrier layer 20b-20d includes a p-type barrier portion 22 doped with p-type impurity and an n-type barrier portion 21 undoped or doped with n-type impurity. The barrier layer 20e adjacent to the n-type GaN layer 3 is undoped or doped with n-type impurity.

This can compensate the polarization electric field not only in the well layer 10a but also in the well layers 10b-10d. Thus, the light emission efficiency can be increased.

On the other hand, in the semiconductor light emitting device 500 shown in FIG. 8B, a barrier layer doped with p-type impurity and a barrier layer undoped or doped with n-type impurity are alternately provided in the barrier layers 20a-20f.

More specifically, the barrier layer 20a adjacent to the p-type AlGaN layer 6 and the barrier layers 20c and 20e are doped with p-type impurity. The barrier layers 20b, 20d, and 20f are undoped or doped with n-type impurity.

This can compensate the polarization electric field in the well layers 10a, 10c, and 10e. Thus, the light emission efficiency in each quantum well can be increased. On the other hand, in the well layers 10b and 10d, the conduction band E_{C} and the valence band E_{V} are shifted to the direction of increasing the electron potential variation Δφ_{b}. Hence, the light emission efficiency cannot be expected to increase in the well layers 10b and 10d. However, the light emission efficiency of the overall light emitting layer including the well layers 10a-10e can be increased.

In the above description of the first to third embodiments, the n-type semiconductor layer, the p-type semiconductor layer, and the barrier layer are made of GaN, and the semiconductor layer constituting the quantum well is made of InGaN. However, the embodiments are not limited to these materials. For instance, the so-called GaN-based nitride semiconductors represented by the composition formula AlₓIn_{y}Ga_{1-x-y}N (0≦x≦1, 0≦y≦1, 0≦x+y≦1) can be suitably combined to form the quantum well structure. Furthermore, clearly, the embodiments according to the invention are applicable to semiconductor light emitting devices based on semiconductor materials in which a polarization electric field is induced in the quantum well.

In this description, the “nitride semiconductor” includes group III-V compound semiconductors of BₓIn_{y}Al_{z}Ga_{1-x-y-z}N (0≦x≦1, 0≦y≦1, 0≦z≦1, 0≦x+y+z≦1). Furthermore, the “nitride semiconductor” also includes mixed crystals containing e.g. phosphorus (P) or arsenic (As) in addition to nitrogen (N). Furthermore, the “nitride semiconductor” also includes those further containing various elements added for controlling various material properties such as conductivity type, and those further containing various unintended elements.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
an n-type semiconductor layer;
a p-type semiconductor layer; and
a light emitting layer provided between the n-type semiconductor layer and the p-type semiconductor layer, and including at least one quantum well,
and the quantum well adjacent to the p-type semiconductor layer including a first barrier layer and a second barrier layer, the first barrier layer nearer to the p-type semiconductor layer being doped with p-type impurity.

2. The device according to claim 1, wherein the second barrier layer is doped with n-type impurity.

3. The device according to claim 1, wherein electric field generated in the quantum well is reduced by p-type impurity concentration of the first barrier layer.

4. The device according to claim 1, wherein a peak of electron wavefunction coincides with a peak of hole wavefunction in the quantum well adjacent to the p-type semiconductor layer.

5. The device according to claim 1, wherein electron potential is located at an equal level on both ends of the quantum well adjacent to the p-type semiconductor layer.

6. The device according to claim 1, wherein the light emitting layer includes a nitride semiconductor and contains magnesium (Mg) as the p-type impurity.

7. The device according to claim 2, wherein the light emitting layer includes a nitride semiconductor and contains silicon (Si) as the n-type impurity.

8. The device according to claim 1, wherein the first barrier layer contains p-type impurity at a concentration higher than background level without impurity doping.

9. The device according to claim 1, wherein
the light emitting layer includes a plurality of the quantum wells and a plurality of the barrier layers, each of the barrier layers having a portion containing the p-type impurity; and the portion containing the p-type impurity is in contact with each edge of the quantum wells on the p-type semiconductor layer side.

10. The device according to claim 9, wherein each of the barrier layers has a portion containing n type impurity, the portion containing the n type impurity being in contact with each edge of the quantum wells on the n-type semiconductor layer side.

11. The device according to claim 1, wherein
the light emitting layer includes a plurality of the quantum wells, a plurality of the barrier layers containing p-type impurity and a plurality of the barrier layers undoped or doped with n-type impurity, the barrier layer containing the p type impurity and the barrier layer undoped or doped with the n type impurity being alternately provided.

12. The device according to claim 1, further comprising:
a block layer between the light emitting layer and the p-type semiconductor layer, the block layer being configured to suppress flow of electrons from the light emitting layer to the p-type semiconductor layer.

13. The device according to claim 1, wherein each of the n-type semiconductor layer, the p-type semiconductor layer, and the light emitting layer includes a GaN-based nitride semiconductor represented by composition formula AlₓIn_{y}Ga_{1-x-y}N (0≦x≦1, 0≦y≦1, 0≦x+y≦1).

14. The device according to claim 13, wherein each of the n-type semiconductor layer and the p-type semiconductor layer includes GaN, and
the light emitting layer includes the quantum well made of a barrier layer including GaN and a well layer including an InₓGa₁₋ₓN layer (x=0.1-0.15).

15. The device according to claim 14, wherein the first barrier layer contains p-type impurity in a concentration range of 1×10¹⁹-1×10²⁰ cm⁻³.

16. The device according to claim 14, wherein the barrier layer has a thickness of 4-10 nm, and the well layer has a thickness of 2-5 nm.

17. The device according to claim 14, further comprising:
a p-type AlGaN layer between the light emitting layer and the p-type semiconductor layer.

18. A method for manufacturing a semiconductor light emitting device, comprising:
sequentially forming an n-type semiconductor layer, a light emitting layer including at least one quantum well, and a p-type semiconductor layer,
and the quantum well adjacent to the p-type semiconductor layer including a first barrier layer and a second barrier layer, the first barrier layer nearer to the p-type semiconductor layer being doped with p-type impurity at a timing delayed from start of growth of the first barrier layer.

19. The method according to claim 18, wherein added amount of doping gas containing the p-type impurity is gradually increased from the start of growth of the first barrier layer.

20. The method according to claim 18, wherein cyclopentadienylmagnesium (Cp₂Mg) is added to raw materials of the first barrier layer.
